(19) United States
(12) Patent Application Publication
(10) Pub. No.: US 2013/0049750 A1
(43) Pub. Date: Feb. 28, 2013

(54) Giant Magnetoresistance Current Sensor

(71) Applicants: Jinliang He, Beijing (CN); Yong Ouyang, Beijing (CN); Jun Hu, Beijing (CN); Shanxiang Wang, Stanford, CA (US); Shijie Ji, Beijing (CN); Rong Zeng, Beijing (CN); Bo Zhang, Beijing (CN); Zhanqing Yu, Beijing (CN)

(72) Inventors: Jinliang He, Beijing (CN); Yong Ouyang, Beijing (CN); Jun Hu, Beijing (CN); Shanxiang Wang, Stanford, CA (US); Shijie Ji, Beijing (CN); Rong Zeng, Beijing (CN); Bo Zhang, Beijing (CN); Zhanqing Yu, Beijing (CN)

(73) Assignee: Tsinghua University, Beijing (CN)

(21) Appl. No.: 13/482,554

(22) Filed: May 29, 2012

(30) Foreign Application Priority Data
Aug. 31, 2011 (CN) 201110255549.1

(51) Int. Cl. G01R 33/09

(52) U.S. Cl. 324/252

(57) ABSTRACT

A giant magnetoresistance current sensor comprises an amorphous alloy magnetic ring having an air gap; a DC magnetic bias coil wound onto the amorphous alloy magnetic ring; a DC constant current source supplying power for the DC magnetic bias coil; a giant magnetoresistance chip disposed in the air gap and having positive and negative outputs; an instrument amplifier having a non-inverting input connected to the positive output of the giant magnetoresistance chip, and an inverting input connected to the negative output of the giant magnetoresistance chip; an operational amplifier having a non-inverting input connected to an output of the instrument amplifier; a voltage following resistance connected between an inverting input and an output of the operational amplifier; an analog to digital converter having an input connected to the output of the operational amplifier; and a digital tube display connected to an output of the analog to digital converter.

### CROSS REFERENCE TO RELATED APPLICATIONS

This application claims priority and benefits of Chinese Patent Application No. 201110255549.1, filed with State Intellectual Property Office, P. R. C. on Aug. 31, 2011, the entire content of which is incorporated herein by reference.

### FIELD

Embodiments of the present disclosure generally relates to a power system measurement, more particularly, to giant magnetoresistance current sensor.

### BACKGROUND ART

Generally, there are three kinds of current sensors for power system measurement: conventional electromagnetic current transformer, optical fiber current sensor and Hall-effect current sensor.

The conventional electromagnetic current transformer operates based on a coil principle, that is, the conventional electromagnetic current transformer measures current through coil induction. This kind of electromagnetic current transformer is heavy in weight, huge in volume, expensive in manufacturing cost, difficult to install, and high in insulation requirements, an electrical isolation can not be carried out between the primary side and the secondary side, and can only measure AC, so that the conventional electromagnetic current transformer is incapable of applying in a large-scale distributed monitoring. Moreover, the optical fiber current sensor is hardly applied widely because it is high in cost and tends to be influenced by environmental factor. Finally, though the Hall-effect current sensor has been used in distribution network, however, the Hall-effect current sensor is not capable of applying in a current measurement with high precision requirements because of a lower sensitivity and a high energy consumption thereof.

### SUMMARY

Embodiments of the present disclosure seek to solve at least one of the problems existing in the prior art to at least some extent, or to provide a consumer with a useful commercial choice.

The giant magnetoresistance current sensor according to embodiments of the present disclosure may apply a magnetic field measurement technology based on giant magnetoresistance effect to the power system, and may calculate the intensity and direction of a current by measuring the magnetic field generated around the current, therefore, it can satisfy requirements of a large-scale distributed monitoring in the smart grid.

Embodiments of the present disclosure provide a giant magnetoresistance current sensor, comprising: an amorphous alloy magnetic ring having an air gap; a DC magnetic bias coil wound onto the amorphous alloy magnetic ring; a DC constant current source to supply power for the DC magnetic bias coil; a giant magnetoresistance chip disposed in the air gap and having a positive output and a negative output; an instrument amplifier having a non-inverting input connected to the positive output of the giant magnetoresistance chip, and an inverting input connected to the negative output of the giant magnetoresistance chip; an operational amplifier having a non-inverting input connected to an output of the instrument amplifier; a voltage following resistance connected between an inverting input and an output of the operational amplifier; an analog to digital converter having an input connected to the output of the operational amplifier; and a digital tube display connected to an output of the analog to digital converter.

In an embodiment, the amorphous alloy magnetic ring has a radius r of about 5 cm, a thickness l of about 1 cm and a width h of about 2 cm.

In an embodiment, a width d of the air gap of the amorphous alloy magnetic ring is about 1 cm.

The giant magnetoresistance current sensor according to embodiments of the present disclosure may measure the DC and AC currents. Comparing to the conventional electromagnetic current transformer, the optical fiber current sensor and the Hall-effect current sensor, the giant magnetoresistance current sensor according to embodiments of the present disclosure is small in volume, low in cost and energy consumption, wide in frequency response, high in sensitivity and good in stability, so that the giant magnetoresistance current sensor according to embodiments of the present disclosure may satisfy requirements of green energy and large-scale distributed monitoring of the smart grid.

The above summary of the present disclosure is not intended to describe each disclosed embodiment or every implementation of the present disclosure. The figures and the detailed description which follow more particularly exemplify illustrative embodiments.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference the accompanying drawings, in which:

FIG. 1 is a circuit schematic view of the giant magnetoresistance current sensor according to embodiments of the present disclosure; and

FIG. 2 is a structural schematic view of the amorphous alloy magnetic ring according to embodiments of the present disclosure.

### REFERENCE NUMERICAL

1—wire to be tested; 2—amorphous alloy magnetic ring; 3—DC magnetic bias coil;

GMR—giant magnetoresistance chip; A—instrument amplifier;

AMP—operational amplifier; R—voltage following resistance;

A/D—analog to digital converter; LED—digital tube display; DC—DC constant current source

### DETAILED DESCRIPTION

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

it is to be noted that, through the description and claims of this specification, the words “comprise”, “include”, “have” and variations thereof, such as “comprising”, “comprises”, “includes” or “including”, “has” or “having”, are not intended to exclude other variants or additional components, integers or steps.

In the specification, relative terms such as “central”, “longitudinal”, “lateral”, “front”, “rear”, “right”, “left”, “lower”, “upper”, “horizontal”, “vertical”, “above”, “below”, “up”, “top”, “bottom” as well as derivative thereof (e.g., “horizontally”, “downwardly”, “upwardly”, etc.) should be construed to refer to the orientation as then described or as shown in the drawings under discussion. These relative terms are for convenience of description and do not require that the present disclosure be constructed or operated in a particular orientation. Terms concerning attachments, coupling and the like, such as “connected” and “interconnected”, refer to a relationship wherein structures are secured or attached to one another either directly or indirectly through intervening structures, as well as both movable or rigid attachments or relationships, unless expressly described otherwise.

In addition, terms such as “first” and “second” are used herein for purposes of description and are not intended to indicate or imply relative importance or significance.

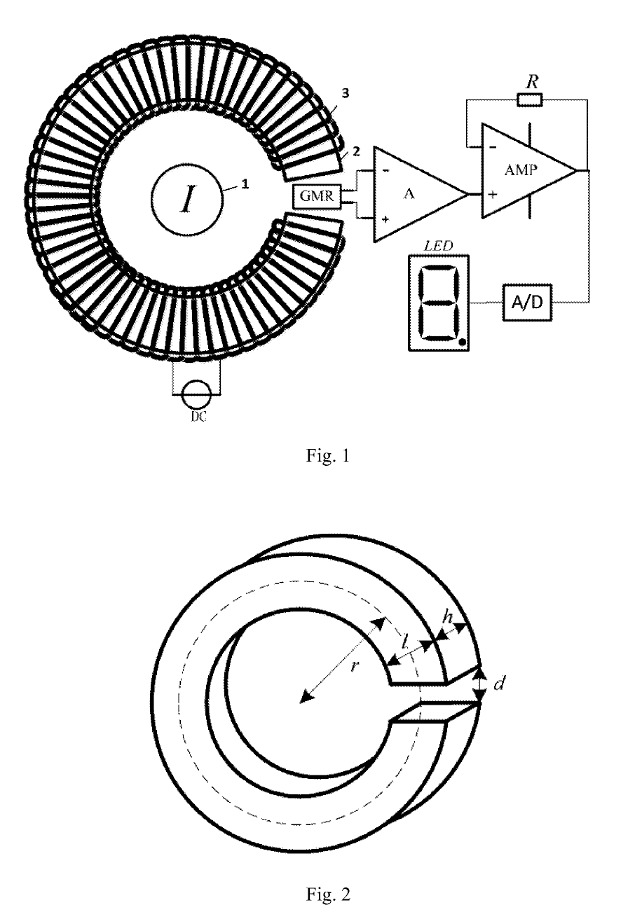

The giant magnetoresistance current sensor according to embodiments of the present disclosure will be described below with reference of FIGS. 1 and 2.

As shown in FIG. 1, a giant magnetoresistance current sensor according to an embodiment of the present disclosure comprises an amorphous alloy magnetic ring 2, a DC magnetic bias coil 3, a DC constant current source DC, a giant magnetoresistance chip GMR, an instrument amplifier A, an operational amplifier AMP, a voltage following resistance R, an analog to digital converter A/D and a digital tube display LED.

The DC magnetic bias coil 3 is wound onto the amorphous alloy magnetic ring 2 and is supplied power by the DC constant current source DC. A wire 1 to be tested may pass through the amorphous alloy magnetic ring 2. The amorphous alloy magnetic ring 2 may have an air gap and the giant magnetoresistance chip GMR having a positive output and a negative output may be disposed in the air gap.

The instrument amplifier A may have a non-inverting input and an inverting input. The non-inverting input of the instrument amplifier A may be connected to the positive output of the giant magnetoresistance chip GMR, and the inverting input of the instrument amplifier A may be connected to the negative output of the giant magnetoresistance chip GMR.

The voltage following resistance R may be connected between an inverting input and an output of the operational amplifier AMP, and the analog to digital converter A/D may have an input connected to the output of the operational amplifier AMP.

The digital tube display LED may be connected to an output of the analog to digital converter A/D. The digital tube display may adopt a digital tube LED display.

As shown in FIG. 2, the amorphous alloy magnetic ring 2 may have a radius r of about 5 cm, a thickness l of about 1 cm and a width h of about 2 cm. The air gap of the amorphous alloy magnetic ring 2 may have a width d of about 1 cm. As shown in FIGS. 1 and 2, the air gap may be formed by cutting off a section of the amorphous alloy magnetic ring 2.

An operation principle of the giant magnetoresistance current sensor according to embodiments of the present disclosure will be described as follows:

Firstly, the amorphous alloy magnetic ring 2 may be a circular ring. The amorphous alloy magnetic ring 2 fits over the wire to be tested, in other words, the wire to be tested passes through the amorphous alloy magnetic ring 2. Hence, the amorphous alloy magnetic ring 2 may gather a magnetic field generated by a current in the wire to be tested.

Secondly, the giant magnetoresistance chip GMR made from multiple-layer films may be disposed in the air gap, and the direction of a sensitive axis is consistent with the magnetic flux within the amorphous alloy magnetic ring 2, that is, the direction of a sensitive axis is in line with the magnetic flux within the amorphous alloy magnetic ring 2.

Finally, a voltage signal of the giant magnetoresistance chip GMR may be transformed and converted by electrically connecting the giant magnetoresistance chip GMR to a signal amplification circuit, so as to calculate the current in the wire to be tested.

In a situation where the magnetic field is weak, a linear characteristic of the giant magnetoresistance chip GMR is poor, and the giant magnetoresistance chip GMR may not identify the direction of the magnetic field. In order to solve this problem, an appropriate number of turns of the DC magnetic bias coil 3, through which a DC current with appropriate intensity and direction passes, may be wound onto the amorphous alloy magnetic ring 2, so that a zero point of the giant magnetoresistance current sensor may be transferred into a linear area, thus solving the above mentioned problem.

An internal structure of the giant magnetoresistance chip GMR may adopt a Wheatstone bridge structure. The DC constant current source DC may be used to supply power to the DC magnetic bias coil 3, so that the voltage signal of the giant magnetoresistance chip GMR may have a linear relationship with the magnetic field generated by the wire to be tested.

As shown in FIG. 1, the wire 1 to be tested may pass through the amorphous alloy magnetic ring 2, and the magnetic field generated by the current in the wire 1 to be tested may be gathered within the amorphous alloy magnetic ring 2.

The giant magnetoresistance chip GMR may be disposed in the air gap. By measuring the magnetic field within the air gap, the giant magnetoresistance chip GMR may output the voltage signal. The voltage signal may be amplified and transformed by the instrument amplifier A and a voltage follower (which may be consisted of the operational amplifier AMP and the voltage following resistance R).

Next, the output voltage signal may be converted to a digital signal by the analog to digital converter A/D, and finally displayed by the digital tube display LED. The display signal and the current in the wire 1 to be tested may be one-to-one correspondence. The DC constant current source DC may provide a constant current to the DC magnetic bias coil 3, so as to provide an appropriate DC magnetic biasing for the giant magnetoresistance chip GMR.

Reference throughout this specification to “an embodiment,” “some embodiments,” “one embodiment”, “another example,” “an example,” “a specific examples,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example, “in an example,” “in a specific examples,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments can not be construed to limit the present disclosure, and changes, alternatives, and modifications can be made in the embodiments without departing from spirit, principles and scope of the present disclosure.

What is claimed is:

1. A giant magnetoresistance current sensor, comprising:
an amorphous alloy magnetic ring having an air gap;
a DC magnetic bias coil wound onto the amorphous alloy magnetic ring;
a DC constant current source to supply power for the DC magnetic bias coil;
a giant magnetoresistance chip formed by multi-layer films and disposed in the air gap and having a positive output and a negative output;
an instrument amplifier having a non-inverting input connected to the positive output of the giant magnetoresistance chip, and an inverting input connected to the negative output of the giant magnetoresistance chip;
an operational amplifier having a non-inverting input connected to an output of the instrument amplifier;
a voltage following resistance connected between an inverting input and an output of the operational amplifier;
an analog to digital converter having an input connected to the output of the operational amplifier; and
a digital tube display connected to an output of the analog to digital converter.

2. The giant magnetoresistance current sensor as set forth in claim 1, wherein the amorphous alloy magnetic ring has a radius r of about 5 cm, a thickness l of about 1 cm and a width h of about 2 cm.

3. The giant magnetoresistance current sensor as set forth in claim 2, wherein a width d of the air gap of the amorphous alloy magnetic ring is about 1 cm.
